(19) United States
(12) Patent Application Publication
(10) Pub. No.: US 2011/0002746 A1
(43) Pub. Date: Jan. 6, 2011

(54) Method of Assessing a Multilayer Strata for Rock Bolt Installation

(75) Inventor: David W. Evans, Wallsend (AU)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: DYWIDAG-SYSTEMS INTERNATIONAL PTY LIMITED, Bennett's Green (AU)

(21) Appl. No.: 12/813,938

(22) Filed: Jun. 11, 2010

(30) Foreign Application Priority Data
Jun. 12, 2009 (AU) AU2009902703

(51) Int. Cl. E21D 20/02; E21D 21/00; G01R 1/06

(52) U.S. Cl. 405/259.5; 405/259.1; 324/149

(57) ABSTRACT

A method of assessing a multilayer strata (1) for rock bolt installation through a strata face (2) of said strata (1), comprises measuring potential differences between a first layer (3) of the strata (1) and each of one or more further layers (4, 5, 6, 7) of the strata (1).

### TECHNICAL FIELD

The present invention relates to the field of strata control and in particular relates to a method of assessing a multilayer strata, such as in the roof or wall of a mine, tunnel, or other underground excavation, for rock bolt installation. The invention also relates to an associated method of installing a rock bolt in such a multilayer strata.

### BACKGROUND OF THE INVENTION

Various forms of rock bolt are known for securing the roof or wall of underground mines, tunnels or other underground excavations. Rock bolts are typically installed by first drilling a bore hole into the strata face of the strata to be secured. The rock bolt is inserted into the bore hole and its leading end secured to the wall of the bore hole adjacent to its top end, typically involving the use of a two-component resin or a mechanical fixing device such as a barrel and wedge assembly. The trailing end of the rock bolt is then secured to the strata face, typically by way of a nut that is threaded on to the trailing end of the rock bolt, bearing against a washer plate that engages the strata face adjacent to the bore hole opening.

To distribute load transfer between the rock bolt and the strata along a significant length of the rock bolt, and to protect the rock bolt against corrosion, a cementitious grout is often injected into the annular cavity between the rock bolt and the bore hole wall so as to at least partially encapsulate the rock bolt. Alternatively, or additionally, for resin fixed installations, the two-component resin securing the leading end of the rock bolt may be utilised in a sufficient volume to encapsulate a significant length of the rock bolt. Sometimes grout or resin encapsulation still leaves the lowermost 500 mm or so of the rock bolt unencapsulated.

Rock bolts are formed of relatively ductile high tensile steel which enables some movement and ductile elongation of the rock bolt with the strata for applied loads less than that of the ultimate tensile strength of the rock bolt. When rock bolts perform according to their design, yet fail as a result of their ultimate tensile strength being exceeded, the failure is characterised by significant elongation and necking of the rock bolt prior to ultimate failure. Some rock bolt failures, however, do not exhibit the ductile type of failure that was intended. In such instances, a brittle type of failure of the bolt has been exhibited, which indicates a sudden and catastrophic failure of the bolt without any necking or significant elongation. It has been hypothesised that such failures result from stress corrosion cracking whereby microscopic cracks develop and grow when the metal is subjected to combined tensile and bending loads within a corrosive environment. The metal becomes embrittled at the point of crack propagation through localised hydrogen embrittlement effects. The microscopic cracks may eventually grow to a critical length which then leads to a sudden catastrophic failure of the rock bolt.

The present inventor has found that, in several examples of such failures, the failure has occurred within a clay layer of a multilayer strata. The present inventor has also found that a potential difference existed between the clay band in such instances of failure and the strata face. It is believed that such a potential difference provides for a flow of current through the bolt between the strata face and clay band, promoting hydrogen embrittlement and stress corrosion cracking of the rock bolt material.

### OBJECT OF THE INVENTION

It is an object of the present invention to reduce the susceptibility of rock bolt installations in multilayer stratas to brittle failure.

### SUMMARY OF THE INVENTION

In a first aspect, the present invention provides a method of assessing a multilayer strata for rock bolt installation through a strata face of said strata, said method comprising the step of measuring potential difference between a first layer of said strata and each of one or more further layers of said strata.

Typically, said first layer of said strata defines said strata face and said potential difference is measured at said strata face.

Typically, said method comprises:

drilling a bore hole through said strata face;

applying a first probe of a voltmeter to said first layer of said strata, said first probe having a first polarity;

inserting a second probe of said voltmeter into said bore hole and traversing said second probe along said bore hole so as to engage a wall of said bore hole at each of said one or more further layers of said strata, said second probe having an opposing second polarity; and

measuring potential difference with said voltmeter between said first and second probes when said second probe is engaged with each of said one or more further layers of said strata.

Typically, said second probe is traversed at least substantially continuously along substantially the entire depth of said bore hole.

In an alternate form, said method comprises:

applying a first probe of a voltmeter to said first layer of strata, said first probe having a first polarity;

inserting a second probe of said voltmeter into a bore hole of a failed rock bolt installation in said strata, said bore hole extending through said strata face, engaging said second probe with a failed end of a failed rock bolt of said failed rock bolt installation, said failed end of said failed rock bolt being located in and engaging a said further layer of said strata, said second probe having an opposing second polarity; and

measuring potential difference with said voltmeter between said first and second probes when said second probe is engaged with said further layer of said strata.

In a second aspect the present invention provides a method of installing a rock bolt in a multilayer strata, said method comprising the steps of:

drilling a bore hole in a strata face of said strata:

measuring potential difference between a first layer of said strata and each of one or more further layers of said strata at a wall of said bore hole;

inserting a rock bolt into said bore hole;

securing a leading end of said rock bolt to said strata;

securing a trailing end of said rock bolt to said strata face; and

insulating said rock bolt over all portions of said rock bolt located in layers of said strata for which the measured potential difference between said first layer of said strata and the respective said layer exceeds a predetermined threshold.

Typically, said first layer of said strata defines said strata face and said potential difference is measured at said strata face.

Typically, said rock bolt is insulated by encapsulating said portions of said rock bolt with an insulating material.

The rock bolt may be insulated prior to securing said trailing end of said rock bolt to said strata face.

The insulating material may be a cementitious grout and/or a resin.

The rock bolt may be insulated prior to inserting said rock bolt into said bore hole.

The insulating material may be in the form of a plastic sheath or a coating applied to said rock bolt.

Typically, said potential difference is measured by:

applying a first probe of a voltmeter to said first layer, said first probe having a first polarity;

inserting a second probe of said voltmeter into said bore hole and traversing said second probe along said hole so as to engage said wall of said bore hole at each of said one or more further layers of said strata, said second probe having an opposing second polarity;

measuring potential difference with said voltmeter between said first and second probes when said second probe is engaged with each of said one or more further layers of said strata.

Typically, said second probe is traversed at least substantially continuously along substantially the entire depth of said bore hole.

### BRIEF DESCRIPTION OF THE DRAWINGS

Preferred embodiments of the present invention will now be described, by way of example only, with reference to the accompanying drawings wherein:

FIG. 1 is a cross-sectional front elevation view of a method of assessing a multilayer strata for rock bolt installation;

FIG. 2 is a cross-sectional front elevation view of a rock bolt installation;

FIG. 3 is a front elevation view of an insulated rock bolt;

FIG. 4 is a cross-sectional front elevation view of an alternate method of assessing a multi-layer strata for rock bolt installation.

### DETAILED DESCRIPTION OF THE PREFERRED EMBODIMENTS

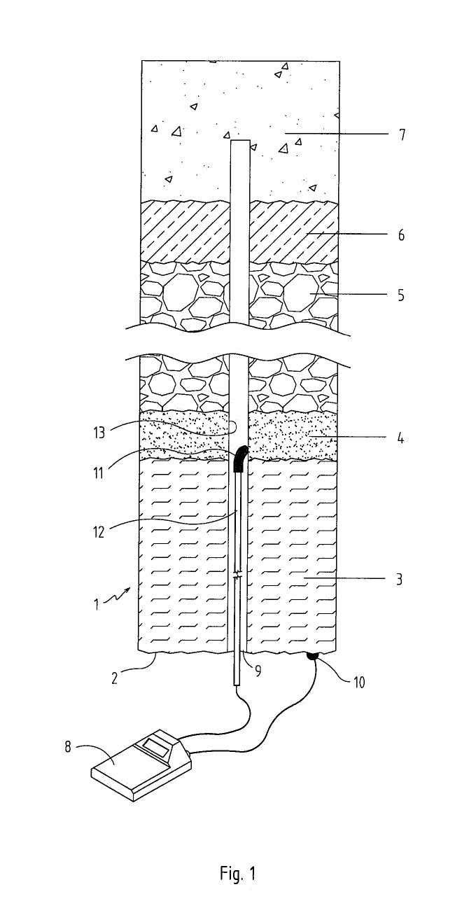

FIG. 1 depicts a multilayer strata 1 intended to be supported by one or more rock bolts to be installed through a strata face 2 of the strata 1. The strata 1 may, for example, form the roof or wall of a mine, tunnel or other underground excavation. The strata 1 depicted includes five separate strata layers of varying material. In the example depicted, a first strata layer 3 that defines the strata face 2 is a coal layer, above which is defined a second layer 4 formed of clay. The third, fourth and fifth layers, 5, 6, 7 are each, for example, formed of rock, clays, conglomerates or coal, depending on the type of strata encountered.

The present inventor has found that rock bolts may fail through stress corrosion cracking if they remain unencapsulated over portions of the rock bolt located within layers of the strata that exhibit a potential difference between the layer and the strata face. For example, the inventor has identified such potential differences between a strata face and bands of clay, such as in the second layer 4 of the strata 1 depicted. A multilayer strata 1 may thus be assessed for rock bolt installation by measuring a potential difference between the strata face 2 and each of one or more layers of the strata 1, such as, for example, each of the second through fifth layers 4-7 of the strata 1. Where any significant potential difference exists, it is believed there would be an increased likelihood of failure of a rock bolt subsequently installed in the strata 1 through stress corrosion cracking if the portion of the rock bolt located in the layer exhibiting the potential difference remains unencapsulated, providing for contact between the rock bolt and strata layer.

One method of measuring potential difference between the strata face 2 and the various layers 4-7 of the strata 1 involves the use of a voltmeter 8, which may be in the form of a multimeter. A bore hole 9 is first drilled through the strata face 2 into the strata 1. The bore hole 9 will typically be a bore hole drilled in preparation for installation of a rock bolt although it is envisaged that a separate hole may be used for the purpose of assessment in the vicinity of the intended rock bolt installation. A first probe 10 of the multimeter is then applied to the strata face 2. The first probe 10 has a first polarity. A second probe 11 of the voltmeter, having an opposing second polarity, is inserted into the bore hole 9 and traversed along the bore hole 9 so as to engage the wall 13 of the bore hole 9 at each of the layers 4-7 of the strata 1. As the second probe 11 is traversed along the bore hole 9, potential difference between the probes 10, 11, and thereby between the strata face 2 and the respective layer of the strata 1 with which the second probe 11 is engaged, is measured. The second probe 11 will typically be mounted on an insulated elongate shaft 12 to facilitate traversing of the second probe 11 through at least substantially the entire depth of the bore hole 9. It is also envisaged, however, that the second probe 11 might only be traversed along a lower part length of the bore hole 9, perhaps traversing over a length of 500 mm to 1 m in situations where encapsulation of a subsequently installed rock bolt from the top of the hole at least down to that level is already envisaged.

Rather than measuring the potential difference between the strata face 2 and each of one or more strata layers of the strata 1, it is envisaged that the first probe 10 might be applied to another one of the layers 4-7 of the strata 1 from within the bore hole 9, with the second probe 11 being applied to one or more of the remaining layers of the strata.

For any layer 4 that has exhibited a potential difference with the strata face 2 beyond a predetermined level, action can be taken to ensure that the rock bolt remains insulated from the strata layer 4 by ensuring that that portion of the rock bolt is encapsulated with grout and/or resin during installation. The present inventor has noted potential differences typically in the order of 200 mV, peaking at up to 600 mV between clay bands where brittle failures have occurred and the associated strata face. Accordingly, suitable predetermined threshold potential differences might be of the order of 250 mV, and may vary dependent on the grade of steel used in the rock bolt.

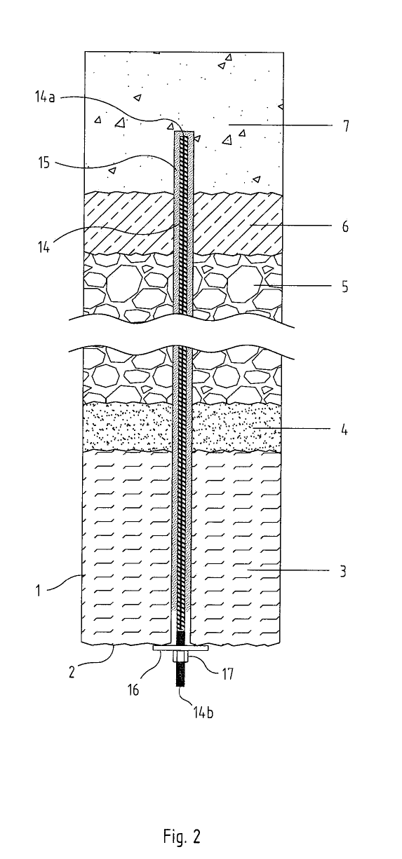

Referring to FIG. 2, once a bore hole 9 in the strata 1 has been assessed utilising the above described method, a rock bolt 14 may be installed in the usual manner by inserting the rock bolt in the bore hole 9 then securing the leading end 14a of the rock bolt 14 to the strata 1. The leading end 14a of the rock bolt 14 may be secured to the strata 1 by any of various known means including the use of a two-component resin 15 or a mechanical fixing device such as an expansion shell. The trailing end 14b of the rock bolt 14 is then secured to the strata face 2, again by any of various known means, typically utilising a nut 17 and washer plate 16 in the traditional manner. The rock bolt 14 is insulated utilising an insulating material, here by using a sufficient quantity of the resin 15 to fully encapsulate portions of the rock bolt 14 located within any strata layer 4 exhibiting a potential difference with the strata face 2 beyond the predetermined threshold. The resin 15 could be applied in one step when securing the leading end 14a of the rock bolt 14 or, alternatively, the leading end 14a of the rock bolt 14 may first be secured utilising a first quantity of resin 15 (or by way of a mechanical fixing device as noted above) and then a further quantity of resin 15 may be used to fully encapsulate the necessary portions of the rock bolt. Alternatively, the resin 15 (or a mechanical fixing device) could be confined to the leading end portion of the rock bolt 14, with remaining portions of the rock bolt 14 located within any strata layer 4 exhibiting a potential difference beyond the predetermined threshold being insulated by encapsulating with cementitious grout.

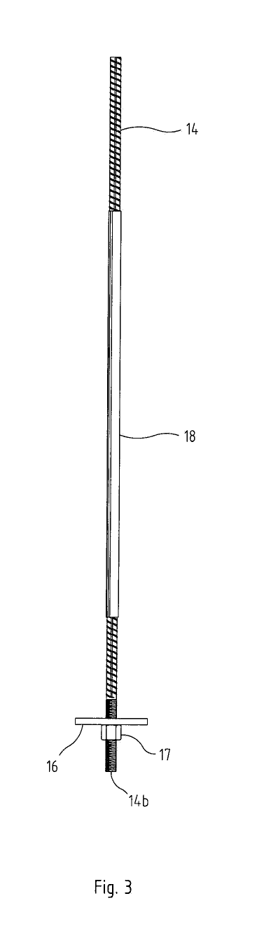

Referring to FIG. 3, to additionally or alternatively insulate the rock bolt, a cylindrical plastic sheath 18, coating or other form of insulating material may be applied to the rock bolt 14 at least to those portions that are to be located within any strata layer 4 requiring insulation, prior to insertion of the rock bolt 14. A coating could be in the form of a painted, powder coated or dipped coating formed of an epoxy or other form of insulating material.

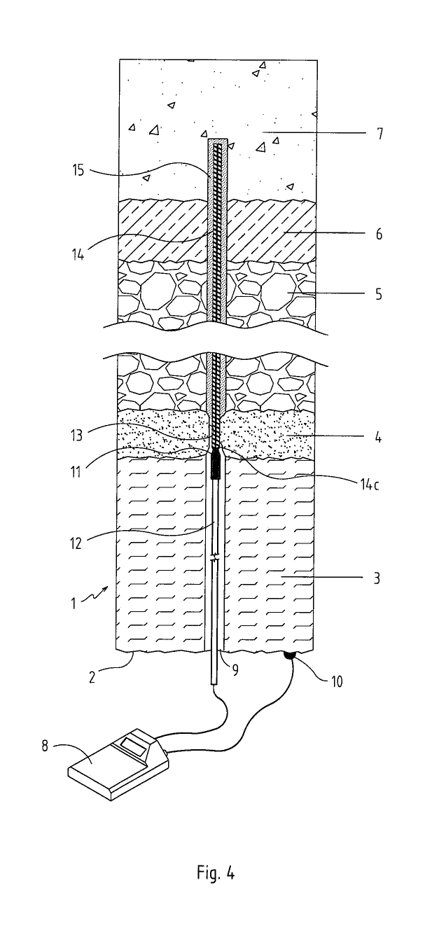

Now referring to FIG. 4, the present method may be utilised in situations where a rock bolt installation has failed so as to assess a possible failure mode and to assess the strata for a subsequent rock bolt installation in the vicinity of the failed installation to replace the same. In this scenario, the first probe 10 of the voltmeter 8 may again be applied to the strata face 2 in the vicinity of the bore hole 9 of the failed rock bolt installation. The second probe 11 of the voltmeter 8 is inserted into the bore hole 9 so as to engage the failed end 14c of the rock bolt 14 of the failed rock bolt installation. The failed end 14c of the failed rock bolt 14 is here shown to be located in the second strata layer 4 and engages the second strata layer 4 here as a result of a shift in the second strata layer 4 bringing the rock bolt 14 into contact with the rock bolt 14 in a trailing, unencapsulated region of the rock bolt 14. Accordingly, the failed end 14c of the failed rock bolt 14 will be at the same potential as the second strata layer 4. The measured potential difference between the failed end 14c of the failed rock bolt 14 and the strata face 2 will thus generally equate to the potential difference between the first strata layer 3 and second strata layer 4. Measured potential differences of the order of 250 mV or greater will thus indicate that the rock bolt 14 failed as a result of stress corrosion cracking and that a further rock bolt installation in the vicinity of the failed rock bolt installation might also be subject to such failure.

1. A method of assessing a multilayer strata for rock bolt installation through a strata face of said strata, said method comprising the step of measuring potential difference between a first layer of said strata and each of one or more further layers of said strata.

2. The method of claim 1, wherein said first layer of said strata defines said strata face and said potential difference is measured at said strata face.

3. The method of claim 1, wherein said method comprises:
drilling a bore hole through said strata face;
applying a first probe of a voltmeter to said first layer of said strata, said first probe having a first polarity; and
inserting a second probe of said voltmeter into said bore hole and traversing said second probe along said bore hole so as to engage a wall of said bore hole at each of said one or more further layers of said strata, said second probe having an opposing second polarity;
measuring potential difference with said voltmeter between said first and second probes when said second probe is engaged with each of said one or more further layers of said strata.

4. The method of claim 3, wherein said second probe is traversed at least substantially continuously along substantially the entire depth of said bore hole.

5. The method of claim 1, wherein said method comprises:
applying a first probe of a voltmeter to said first layer of strata, said first probe having a first polarity;
inserting a second probe of said voltmeter into a bore hole of a failed rock bolt installation in said strata, said bore hole extending through said strata face, engaging said second probe with a failed end of a failed rock bolt of said failed rock bolt installation, said failed end of said failed rock bolt being located in and engaging a said further layer of said strata, said second probe having an opposing second polarity; and
measuring potential difference with said voltmeter between said first and second probes when said second probe is engaged with said further layer of said strata.

6. A method of installing a rock bolt in a multilayer strata, said method comprising the steps of:
drilling a bore hole in a strata face of said strata:
measuring potential difference between said a first layer of said strata and each of one or more further layers of said strata at a wall of said bore hole;
securing a leading end of said rock bolt to said strata;
securing a trailing end of said rock bolt to said strata face;
inserting a rock bolt into said bore hole; and
insulating said rock bolt over all portions of said rock bolt located in layers of said strata for which the measured potential difference between said first layer of said strata and the respective said layer exceeds a predetermined threshold.

7. The method of claim 6, wherein said first layer of said strata defines said strata face and said potential difference is measured at said strata face.

8. The method of claim 6, wherein said rock bolt is insulated by encapsulating said portions of said rock bolt with an insulating material.

9. The method of claim 8, wherein said rock bolt is insulated prior to securing said trailing end of said rock bolt to said strata face.

10. The method of claim 9, wherein said insulating material comprises a cementitious grout and/or a resin.

11. The method of claim 8, wherein said rock bolt is insulated prior to inserting said rock bolt into said bore hole.

12. The method of claim 11, wherein said insulating material is in the form of a plastic sheath.

13. The method of claim 11, wherein said insulating material is in the form of a coating applied to said rock bolt.

14. The method of claim 6, wherein said potential difference is measured by:
applying a first probe of a voltmeter to said first layer, said first probe having a first polarity;
inserting a second probe of said voltmeter into said bore hole and traversing said second probe along said hole so as to engage said wall of said bore hole at each of said one or more further layers of said strata, said second probe having an opposing second polarity;
measuring potential difference with said voltmeter between said first and second probes when said second probe is engaged with each of said one or more further layers of said strata.

15. The method of claim 14, wherein said second probe is traversed at least substantially continuously along substantially the entire depth of said bore hole.
